(19) United States
(12) Patent Application Publication
(10) Pub. No.: US 2025/0301266 A1
(43) Pub. Date: Sep. 25, 2025

(54) SOUND APPARATUS AND VEHICULAR APPARATUS COMPRISING THE SAME

(71) Applicant: LG Display Co., Ltd., Seoul (KR)

(72) Inventors: YongWoo LEE, Paju-si (KR); JounHo LEE, Paju-si (KR); Sooyoun KIM, Paju-si (KR); HwaYoul LEE, Paju-si (KR); Sungtae LEE, Paju-si (KR); Uihyeon JEONG, Paju-si (KR); Daesu KIM, Paju-si (KR)

(73) Assignee: LG Display Co., Ltd., Seoul (KR)

(21) Appl. No.: 19/072,037

(22) Filed: Mar. 6, 2025

(30) Foreign Application Priority Data
Mar. 22, 2024 (KR) 10-2024-0040067

(51) Int. Cl. H04R 17/00; H10N 30/853; H10N 30/87

(52) U.S. Cl. CPC H04R 17/00; H10N 30/853; H10N 30/872; H04R 2499/13

(57) ABSTRACT

In one or more examples, a sound apparatus is configured for use with at least one of a vibration member and an interior material of a vehicular apparatus and configured to output sound. The sound apparatus may include a first electrode layer, a first vibration layer on the first electrode layer, a second electrode layer on the first vibration layer, a first line connected to the first electrode layer and in contact with the vibration member, and a second line connected to the second electrode layer and in contact with the vibration member. A vehicular apparatus including a sound apparatus is also disclosed.

### CROSS-REFERENCE TO RELATED APPLICATIONS

This application claims the benefit of and priority to Korean Patent Application No. 10-2024-0040067 filed on Mar. 22, 2024, the entire contents of which are incorporated herein by reference for all purposes as if fully set forth herein.

### BACKGROUND

### 1. Technical Field

The present disclosure relates to a sound apparatus and a vehicular apparatus comprising the same.

### 2. Description of the Related Art

A vehicle includes a sound apparatus that outputs sound in accordance with an audio signal output from a multimedia device such as a car audio player.

However, the sound apparatus in the vehicle has a difficulty in configuring a sound apparatus due to a spatial restriction inside the vehicle, and has a limitation in outputting desired sound.

The description of the related art should not be assumed to be prior art merely because it is mentioned in or associated with this section. The description of the related art includes information that describes one or more aspects of the subject technology, and the description in this section does not limit the invention.

### SUMMARY

The inventors of the present disclosure have recognized the above-mentioned problems and have conducted various experiments for implementing a sound apparatus capable of being easily disposed in a vehicle or a vehicular apparatus. The inventors of the present disclosure have invented a sound apparatus capable of being easily disposed in a vehicle or a vehicular apparatus through various experiments and a vehicular apparatus comprising the same.

The present disclosure has been made in view of the above problems, and one or more aspects of the present disclosure are directed to providing a sound apparatus capable of being easily disposed in a vehicle or a vehicular apparatus and a vehicular apparatus comprising the same.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and embodiment of the present disclosure, as embodied and broadly described herein, in one or more embodiments, a sound apparatus is configured for use with at least one of a vibration member and an interior material of a vehicular apparatus and configured to output sound. The sound apparatus includes a first electrode layer, a first vibration layer on the first electrode layer, a second electrode layer on the first vibration layer, a first line connected to the first electrode layer and in contact with the vibration member, and a second line connected to the second electrode layer and in contact with the vibration member.

To achieve these and other advantages and embodiment of the present disclosure, as embodied and broadly described herein, in one or more embodiments, a vehicular apparatus comprises a vibration member, an interior material, and at least one sound apparatus, wherein the at least one sound apparatus includes a sound apparatus, and the sound apparatus includes a first electrode layer, a first vibration layer on the first electrode layer, a second electrode layer on the first vibration layer, a first line connected to the first electrode layer and in contact with the vibration member, and a second line connected to the second electrode layer and in contact with the vibration member.

To achieve these and other advantages and embodiment of the present disclosure, as embodied and broadly described herein, in one or more embodiments, a sound apparatus is configured for use with at least one of a vibration member and an interior material of a vehicular apparatus and configured to output sound. The sound apparatus includes a first electrode layer, a first vibration layer on the first electrode layer, a second electrode layer on the first vibration layer, and a second vibration layer between the first electrode layer and the first vibration layer.

To achieve these and other advantages and embodiment of the present disclosure, as embodied and broadly described herein, in one or more embodiments, a vehicular apparatus comprises a vibration member, an interior material, and at least one sound apparatus, wherein the at least one sound apparatus includes a sound apparatus, and the sound apparatus includes a first electrode layer, a first vibration layer on the first electrode layer, a second electrode layer on the first vibration layer, and a second vibration layer between the first electrode layer and the first vibration layer.

According to one or more embodiments of the present disclosure, sound characteristics and/or sound pressure characteristics may be improved.

According to one or more embodiments of the present disclosure, the sound apparatus integrated with the vehicle interior material or the vibration member and the vehicular apparatus comprising the same may be provided.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a view illustrating a sound apparatus for a vehicle according to one embodiment of the present disclosure.

FIG. 2 is a view illustrating a vehicular apparatus according to one embodiment of the present disclosure.

FIG. 3 is a plan view illustrating a sound apparatus according to one embodiment of the present disclosure.

FIG. 4 is a cross-sectional view taken along line I-I′ of FIG. 3.

FIG. 5 is a view illustrating a sound apparatus according to another embodiment of the present disclosure.

FIG. 6 is a view illustrating a sound apparatus according to another embodiment of the present disclosure.

FIG. 7 is a view illustrating a sound apparatus according to another embodiment of the present disclosure.

FIG. 8 is a plan view illustrating a sound apparatus according to another embodiment of the present disclosure.

FIG. 9 is a plan view illustrating a sound apparatus according to another embodiment of the present disclosure.

FIG. 10 is a plan view illustrating a sound apparatus according to another embodiment of the present disclosure.

FIG. 11 is a plan view illustrating a sound apparatus according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known functions or configurations may unnecessarily obscure aspects of the present disclosure, the detailed description thereof may be omitted for brevity. The progression of processing steps and/or operations described is an example; however, the sequence of steps and/or operations is not limited to that set forth herein and may be changed, with the exception of steps and/or operations necessarily occurring in a particular order.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

The shapes, sizes, areas, ratios, angles, numbers, and the like disclosed in the drawings for describing embodiments of the present disclosure are merely examples, and thus, the present disclosure is not limited to the illustrated details.

When the term “comprise,” “have,” “include,” “contain,” “constitute,” “make up of,” “formed of,” or the like is used, one or more other elements may be added unless a term such as “only” or the like is used. The terms used in the present disclosure are merely used in order to describe particular embodiments, and are not intended to limit the scope of the present disclosure. The terms used herein are merely used in order to describe example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompasses all the meanings of the term “can.”

In describing a positional relationship, where the positional relationship between two parts is described, for example, using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” “adjacent to,” “beside,” or “next to” another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It is understood that, although the term “first,” “second,” or the like may be used herein to describe various elements, these elements should not be limited by these terms. These terms are only used to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element or layer is “connected,” “coupled,” “attached,” or “adhered” to another element or layer, the element or layer can not only be directly connected, coupled, attached, or adhered to another element or layer, but also be indirectly connected, coupled, attached, or adhered to another element or layer with one or more intervening elements or layers disposed or interposed between the elements or layers, unless otherwise specified.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

The terms such as a “line” or “direction” should not be interpreted only based on a geometrical relationship in which the respective lines or directions are parallel or perpendicular to each other, and may be meant as lines or directions having wider directivities within the range within which the components of the present disclosure can operate functionally.

The term “at least one” should be understood as including any and all combinations of one or more of the associated listed items. For example, the meaning of “at least one of a first item, a second item, and a third item” denotes the combination of items proposed from two or more of the first item, the second item, and the third item as well as only one of the first item, the second item, or the third item.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C. Furthermore, an expression “element A/element B” may be understood as element A and/or element B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

Features of various embodiments of the present disclosure may be partially or wholly coupled to or combined with each other and may be variously inter-operated, linked or driven together. The embodiments of the present disclosure may be carried out independently from each other or may be carried out together in a co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

FIG. 1 is a view illustrating a sound apparatus for a vehicle according to one embodiment of the present disclosure.

Referring FIG. 1, a vehicular sound apparatus according to an embodiment of the present disclosure may include a sound apparatus 30. The sound apparatus 30 may be disposed or equipped in a vehicle so as to output a sound S toward an internal space IS of a vehicle 10.

The vehicle 10 may include an interior material (or an interior finish material) 130. In the following description, for convenience of description, the “interior material 130” may be referred to as a “vehicular interior material 130”.

The vehicular interior material 130 may include all parts configuring the inside of the vehicle 10, or may include all parts disposed at the internal space IS of the vehicle 10. For example, the vehicular interior material 130 may be an interior member or an inner finishing member of the vehicle 10, but embodiments of the present disclosure are not limited thereto.

The vehicular interior material 130 according to an embodiment of the present disclosure may be configured to be exposed at the internal or indoor space IS of the vehicle 10, in the internal or indoor space IS of the vehicle 10. For example, the vehicular interior material 130 may be configured on one surface (or an interior surface) of at least one of a main frame (or a vehicular body), a side frame (or a side body), a door frame (or a door body), a handle frame (or a steering hub), and a seat frame, which are exposed at the indoor space IS of the vehicle 10. For example, the vehicular interior material 130 may be configured to cover one surface (or an interior surface) of at least one of a main frame (or a vehicular body), a side frame (or a side body), a door frame (or a door body), a handle frame (or a steering hub), and a seat frame, which are exposed at the indoor space IS of the vehicle 10.

The vehicular interior material 130 according to an embodiment of the present disclosure may include a dash board, a pillar interior material (or a pillar trim), a floor interior material (or a floor carpet), a roof interior material (or a headliner), a door interior material (or a door trim), a handle interior material (or a steering cover), a seat interior material, a rear package interior material (or a backseat shelf), an overhead console (or an indoor illumination interior material), a rear view mirror, a glove box, and a sun visor, but embodiments of the present disclosure are not limited thereto.

The vehicular interior material 130 according to an embodiment of the present disclosure may include one or more of metal, wood, rubber, plastic, glass, fiber, cloth, paper, mirror, leather, and carbon, but embodiments of the present disclosure are not limited thereto. The vehicular interior material 130 including a plastic material may be an injection material which is implemented by an injection process using thermosetting resin or thermoplastic resin, but embodiments of the present disclosure are not limited thereto. The vehicular interior material 130 including a fiber material may include one or more of synthetic fiber, carbon fiber (or aramid fiber), and natural fiber, but embodiments of the present disclosure are not limited thereto. The vehicular interior material 130 including a fiber material may include may be a fabric sheet, a knitting sheet, or a nonwoven fabric, but embodiments of the present disclosure are not limited thereto. For example, the paper may be cone paper. For example, the cone paper may be pulp or foam plastic, but embodiments of the present disclosure are not limited thereto. The vehicular interior material 130 including a leather material may include a natural leather or an artificial leather, but embodiments of the present disclosure are not limited thereto.

The vehicular interior material 130 according to an embodiment of the present disclosure may include one or more of a flat portion and a curved portion. For example, the vehicular interior material 130 may have a structure corresponding to a structure of a corresponding vehicular structure material, or may have a structure which differs from the structure of the corresponding vehicular structure material.

According to an embodiment of the present disclosure, the sound apparatus 30 may be disposed at the vehicular interior material 130. The sound apparatus 30 may vibrate the vehicular interior material 130, to generate a sound S based on a vibration of the vehicular interior material 130. For example, the sound apparatus 30 may directly vibrate the vehicular interior material 130, to generate the sound S based on a vibration of the vehicular interior material 130. For example, the sound apparatus 30 may be configured to vibrate the vehicular interior material 130 to output the sound S toward the internal or indoor space IS of the vehicle 10. Therefore, the vehicular interior material 130 may be used as a sound vibration plate. The vehicular interior material 130 may be a vibration plate, a sound vibration plate, or a sound generating plate for outputting the sound S. For example, the vehicular interior material 130 may have a size which is greater than that of the sound apparatus 30, but embodiments of the present disclosure are not limited thereto.

For example, the sound apparatus 30 may be disposed at one or more of a dash board, a pillar interior material, a floor interior material, a roof interior material, a door interior material, a handle interior material, and a seat interior material, or may be disposed in one or more of a rear package interior material, an overhead console, a rear view mirror, a glove box, and a sun visor.

The sound apparatus 30 according to an embodiment of the present disclosure may vibrate a corresponding vehicular interior material 130 through at least one of one or more sound apparatuses 30 disposed at the vehicular interior material 130 to output a realistic sound S and/or stereo sound, including a multichannel, toward the indoor space IS of the vehicle 10.

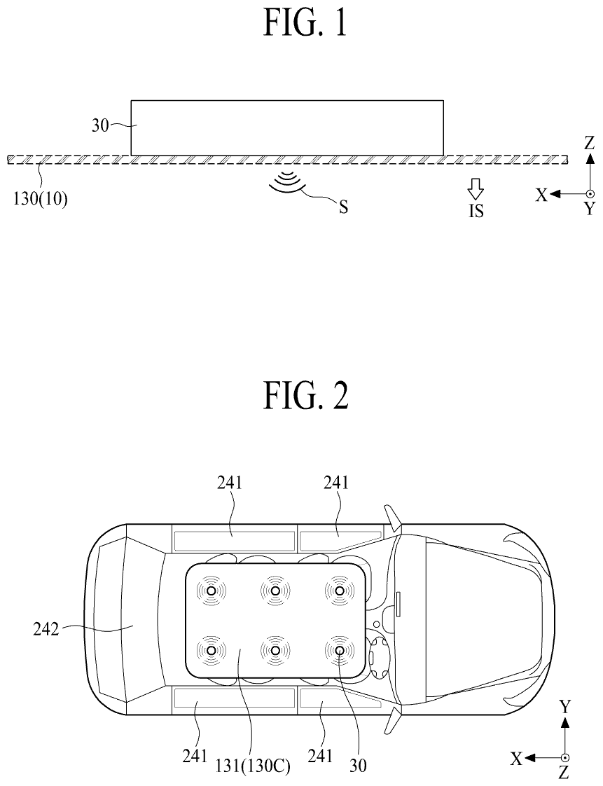

FIG. 2 is a view illustrating a vehicular apparatus according to one embodiment of the present disclosure.

Referring to FIG. 2, the vehicular apparatus according to one embodiment of the present disclosure may include a sound apparatus 30.

When the sound apparatus 30 is disposed in a roof frame, it is difficult to dispose the sound apparatus 30 due to a narrow space of the roof frame. In addition, damage to the sound apparatus 30 may occur due to bending of the roof frame when the sound apparatus 30 is attached to the roof frame.

Accordingly, the inventors of the present disclosure have conducted various experiments that can be disposed in a vehicle interior material 130C or a vibration member 131, which will be described below.

According to the present disclosure, the sound apparatus 30 may be disposed on the vibration member 131. The sound apparatus 30 may be configured to vibrate the vibration member 131 to output sound according to vibration of the vibration member 131. For example, the sound apparatus 30 may directly vibrate the vibration member 131 to output sound according to the vibration of the vibration member 131.

According to the present disclosure, the sound apparatus 30 may be disposed on a vehicle window. The vehicle window of the vehicular apparatus or the vehicle 10 may be at least one of a front window and a side window. The vehicle window may further include at least one of a rear window and a roof window.

According to the present disclosure, the sound apparatus 30 may be disposed on at least one of a side window 241, a rear window 242 and a roof window. For example, the vibration member 131 may be a roof window. For example, the sound apparatus 30 may be disposed in a middle area or a peripheral area of the vehicle window. For example, the sound apparatus 30 may be disposed in a middle area or a peripheral area of at least one of the side window 241, the rear window 242 and the roof window.

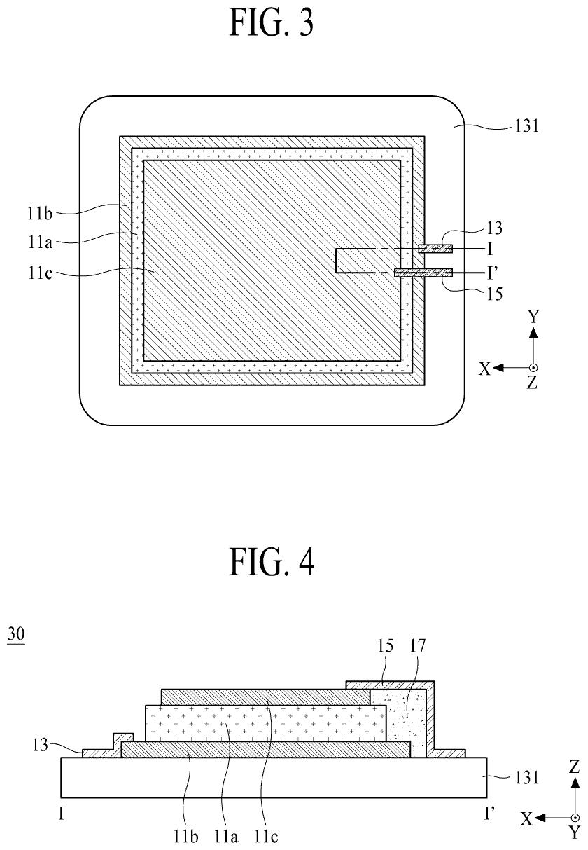

FIG. 3 is a plan view illustrating a sound apparatus according to one embodiment of the present disclosure. FIG. 4 is a cross-sectional view taken along line I-I′ of FIG. 3.

Referring to FIGS. 3 and 4, the sound apparatus 30 according to one embodiment of the present disclosure may be configured to vibrate the vibration member 131. For example, the sound apparatus 30 may be disposed or configured on the vibration member 131. The sound apparatus 30 may be configured to be vibrated (or displaced or driven) in accordance with a driving signal (or vibration driving signal or voice signal) applied thereto, thereby vibrating (or displacing or driving) the vibration member 131. The sound apparatus 30 may include one or more vibration devices. For example, one or more vibration devices may be configured or disposed on the vibration member 131.

The vibration member 131 may be a plate, a vibration plate, a vibration target, a vibration panel, a sound plate, a sound panel, a passive vibration plate, a passive vibration member, a passive vibration panel, a sound output plate, or a sound vibration plate, and the embodiments of the present disclosure are not limited thereto. For example, the vibration member 131 may be made of glass, but the embodiments of the present disclosure are not limited thereto. For example, the vibration member 131 may be a transparent substrate, but the embodiments of the present disclosure are not limited thereto. For example, the sound apparatus 30 may be installed at a roof interior material, but the embodiments of the present disclosure are not limited thereto.

According to the present disclosure, the vibration member 131 may be at least one of the side window 241, the rear window 242, and the roof window.

The sound apparatus 30 according to one embodiment of the present disclosure may be transparent. For example, the sound apparatus 30 may be made of a transparent material layer. For example, the sound apparatus 30 may be a transparent sound apparatus.

According to the present disclosure, the sound apparatus 30 or the vibration device may include a vibration layer 11a. The vibration layer 11a may include a first surface and a second surface different from (or opposite to) the first surface.

According to the present disclosure, the sound apparatus 30 may include a first electrode layer 11b and a second electrode layer 11c. The first electrode layer 11b may be disposed on a first surface of the vibration layer 11a. The second electrode layer 11c may be disposed on a second surface of the vibration layer 11a. The second electrode layer 11c may be disposed on the second surface of the vibration layer 11a, which is different from the first surface of the vibration layer 11a.

For example, the vibration layer 11a may be disposed on the first electrode layer 11b. The second electrode layer 11c may be disposed on the vibration layer 11a.

For example, the vibration layer 11a may include a piezoelectric material (or an electroactive material) having a piezoelectric effect. For example, the piezoelectric material (or the piezoelectric device) may have a characteristic where pressure or twisting is applied to a crystal structure by an external force, a potential difference occurs due to dielectric polarization caused by a relative position change of a positive (+) ion and a negative (−) ion, and a vibration is generated by an electric field based on a voltage applied thereto. For example, the vibration layer 11a may be a piezoelectric layer, a piezoelectric material layer, an electroactive layer, a piezoelectric composite layer, a piezoelectric composite body, or a piezoelectric ceramic composite body, but the embodiments of the present disclosure are not limited thereto.

For example, the vibration layer 11a may be made of a material that may be crystallized at a low heat treatment temperature. For example, the vibration layer 11a may include at least one of a lead zirconate titanate (PZT)-based material, a potassium sodium niobate (KNN)-based material, a barium titanate (BT)-based material, a bismuth (Bi)-based material and aluminum nitride (AlN), but the embodiments of the present disclosure are not limited thereto. The lead zirconate titanate (PZT)-based material may contain lead (Pb), zirconium (Zr) and titanium (Ti). The KNN-based material may be (K,Na)NbO₃. The BT-based material may be BaTiO₃, but the embodiments of the present disclosure are not limited thereto. The Bi-based material may be BiFeO₃, BiNaTiO₃, Bi(Na,K)TiO₃—BaTiO₃—(K,Na)NbO₃ or the like, but the embodiments of the present disclosure are not limited thereto.

For another example, the KNN-based material may be represented by Equation 1 below, but the embodiments of the present disclosure are not limited thereto.

0.96(NaₐK₁₋ₐ)(Nb_{b}T_{1-b})O₃—(0.04-x)MZrO₃-x(Bi_{c}Ag_{1-c})ZrO₃(T=Sb,Ta),(M=Sr,Ba,Ca) Equation 1

In this case, a may be 0.4≤a≤0.6, b may be 0.90≤b≤0.98, c may be 0.4≤c≤0.6, d may be 0≤d≤5.0, and x may be 0≤x≤0.04.

According to the present disclosure, Equation 1 may be doped with Y₂O₃, La₂O₃, or LiF, but is not limited thereto. Accordingly, since pores of the vibration layer 11a may be removed, the vibration layer 11a having high density characteristics may be configured.

For example, the first electrode layer 11b and the second electrode layer 11c may include a transparent conductive material, or a semitransparent conductive material. For example, the transparent or semitransparent conductive material may include one or more of indium tin oxide (ITO) or indium zinc oxide (IZO), but embodiments of the present disclosure are not limited thereto. Therefore, when the vibration member 131 is made of glass, since the first electrode layer 11b and the second electrode layer 11c are made of a transparent material or a translucent material, transmittance of the vibration member 131 may be improved. As another example, the first electrode layer 11b and the second electrode layer 11c may be made of a conductive metal. For example, the first electrode layer 11b and the second electrode layer 11c may be made of one of aluminum (Al), copper (Cu), nickel (Ni), gold (Au), silver (Ag), tin (Sn), platinum (Pt), molybdenum (Mo), and tungsten (W), or their compound, but the embodiments of the present disclosure are not limited thereto. For another example, the first electrode layer 11b and the second electrode layer 11c may be formed of a mesh type, but the embodiments of the present disclosure are not limited thereto.

For example, a size of the first electrode layer 11b may be larger than that of the second electrode layer 11c, but the embodiments of the present disclosure are not limited thereto. For example, a size of the vibration layer 11a may be larger than that of the second electrode layer 11c, but the embodiments of the present disclosure are not limited thereto. For example, the vibration layer 11a may surround the second electrode layer 11c.

For example, a thickness of the first electrode layer 11b may be the same as that of the second electrode layer 11c, but the embodiments of the present disclosure are not limited thereto. For example, a thickness of the vibration layer 11a may be less than one of the thickness of the first electrode layer 11b and the thickness of the second electrode layer 11c, but the embodiments of the present disclosure are not limited thereto. For example, the thickness of the first electrode layer 11b and the thickness of the second electrode layer 11c may be 0.02 μm to 1.0 μm, but the embodiments of the present disclosure are not limited thereto. For example, the thickness of the vibration layer 11a may be 0.1 μm to 1.2 μm, but the embodiments of the present disclosure are not limited thereto. Since the thickness of the first electrode layer 11b, the thickness of the second electrode layer 11c, and/or the thickness of the vibration layer 11a are adjusted, transparent characteristics of the sound apparatus 30 or the vibration device may be improved.

The sound apparatus 30 or the vibration device may include a first line 13 and a second line 15. The first line 13 may be connected to the first electrode layer 11b. For example, the first line 13 may be provided on a side of the first electrode layer 11b. The first line 13 may be in contact with or in direct contact with the vibration member 131. The second line 15 may be connected to the second electrode layer 11c. For example, the second line 15 may be connected to a portion of an upper surface of the second electrode layer 11c. The second line 15 may be in contact with or in direct contact with the vibration member 131.

The first line 13 and the second line 15 may be made of a conductive material. For example, each of the first line 13 and the second line 15 may be a conductive member or a conductive tape, but the embodiments of the present disclosure are not limited thereto. For example, the first line 13 and the second line 15 may be conductive lines formed by coating and curing a conductive material.

A driving signal may be applied to the sound apparatus 30 or the vibration device through the first line 13 and the second line 15. Accordingly, the sound apparatus 30 or the vibration device may be configured to be vibrated (or displaced or driven) in accordance with a driving signal (or a vibration driving signal or a voice signal) applied thereto, thereby vibrating (or displacing or driving) the vibration member 131.

According to the present disclosure, a portion of the first line 13 and the second line 15 may be a pad portion. The pad portion that is a portion of the first line 13 and the second line 15 may be electrically connected to a vibration driving circuit (or a sound driving circuit). The vibration driving circuit (or the sound driving circuit) may be electrically connected to the pad portion through a signal cable (or a signal supply member). For example, the signal cable may be transparent. For example, the signal cable may include a transparent signal line.

The sound apparatus 30 or the vibration device may further include an insulating layer 17 around the second electrode layer 11c. For example, the insulating layer 17 may be on one or more sides of the vibration layer 11a and the second electrode layer 11c. For example, the insulating layer 17 may be on one or more sides of the first vibration layer 11a and the second electrode layer 11c. The insulating layer 17 may be on each side of the vibration layer 11a and the second electrode layer 11c and on a side of the first electrode layer 11b. The insulating layer 17 may be made of zinc oxide (ZnO) or aluminum oxide (Al₂O₃), but the embodiments of the present disclosure are not limited thereto.

For example, the second line 15 may be provided on a portion of the upper surface of the second electrode layer 11c and around the insulating layer 17. The second line 15 may be configured to cover a portion of the upper surface of the second electrode layer 11c and the insulating layer 17.

According to the present disclosure, an adhesive member may be further provided between the substrate or the vibration member 131 and the first electrode layer 11b. The adhesive member may improve an adhesive force between the vibration member 131 and the first electrode layer 11b. For example, the adhesive member may include epoxy resin, acrylic resin, silicone resin, or urethane resin, but embodiments of the present disclosure are not limited thereto.

Referring to FIG. 2 together, a vehicular apparatus may include a vibration member 131 and a sound apparatus 30 disposed on the vibration member 131. The vibration member 131 may be made of glass. The sound apparatus 30 may be configured to vibrate the vibration member 131 or to be directly vibrated, thereby outputting sound according to the vibration of the vibration member 131.

Referring to FIG. 2 together, the sound apparatus 30 may be configured to be transparent, and may be disposed in a middle area or a peripheral area of the vehicle window 230. For example, the sound apparatus 30 may be disposed in a middle area or a peripheral area of one or more of the side window 241, the rear window 242 and the roof window.

The sound apparatus 30 or the vibration device according to the present disclosure may be disposed on the vibration member 131 made of glass, and a transparent sound apparatus 30 or a transparent vibration device may be provided.

According to the present disclosure, the sound apparatus 30 integrated with the vibration member 131 or the vehicle interior material may be provided. For example, the vehicle interior material in which the sound apparatus 30 is integrated may be implemented.

A method of manufacturing the sound apparatus 30 or the vibration device according to the present disclosure may be described as follows.

A method of forming the sound apparatus 30 or the vibration device in a vehicular apparatus or an interior material of a vehicle will be described based on a method by a sputtering process as an example, but the embodiments of the present disclosure are not limited thereto. The interior material of the vehicular apparatus or the vehicle may be a transparent glass or a transparent glass substrate.

In order to configure the transparent vibration layer by using the sputtering process, a parent material for forming a piezoelectric thin film may be manufactured. Although the following description will be based on a method of manufacturing a KNN-based parent material as an example, the embodiments of the present disclosure are not limited thereto.

The parent material for manufacturing the vibration layer 11a may be crack-free and uniform, and may require high-density characteristics. For example, the parent material may be manufactured by a non-template grain growth (non-TGG) method, but the embodiments of the present disclosure are not limited thereto.

The method of manufacturing the parent material may include a step of weighing a raw material (S110), a step of mixing the raw material (S120), a step of calcining and synthesizing the mixed raw material, a step of pulverizing the synthesized parent material, a step of preparing a molded body by molding the parent material, and a step of sintering the molded body to prepare a sintered body. In the following description, conditions according to the method of manufacturing the vibrating layer 11a, for example, temperature, pressure and time do not limit the contents of the present disclosure.

First, the step of weighing the raw material may be weighing a raw material on the basis of a mole ratio to add an appropriate amount of solvent. For example, the step of weighing a raw material may be a process of weighing the raw material to be suitable for a molar ratio of a composition to be synthesized, putting the raw material in a nylon jar and adding an appropriate amount of solvent (e.g., ethanol), but the embodiments of the present disclosure are not limited thereto.

Subsequently, the step of mixing the raw materials may be a mixing and milling the weighed raw materials and a solvent (ethanol) by a ball milling process. For example, the ball milling process may put the weighed raw materials into Nalgene bottle along with YSZ ball and a solvent, and then, the ball milling process may be performed for 12 hours to 36 hours, but embodiments of the present disclosure are not limited thereto.

The embodiment of the present disclosure may further include a drying step to separate a powder mixed with the solvent after the mixing step. The drying step may be performed by separating the raw material, which has been milled, from a ball and discharging the raw material, putting the mixed raw material in a dish and drying the same at a temperature of 90° C. to 100° C. for 3 hours, but the embodiments of the present disclosure are not limited thereto. Accordingly, ethanol mixed with the raw material may be removed.

Subsequently, an embodiment of the present disclosure may include the step of calcining the raw materials. The step of calcining the raw materials may be phase-synthesizing primarily mixed raw materials. The step of phase-synthesis involves finely grinding the dried mixture after the mixing is completed, placing it in an alumina crucible, and heating it in an electric furnace at a heating rate of 5° C. per minute until it reaches 400° C., then maintaining the temperature for 30 minutes. The calcining step may include calcining the compound at 400° C. to 1000° C. for 3 hours to 6 hours, and cool or naturally cool the calcined compound at a room temperature (or a normal temperature), but embodiments of the present disclosure are not limited thereto. For example, the calcination temperature may be 400° C. to 1000° C. and a maintenance time may be 1 hour to 6 hours, but embodiments of the present disclosure are not limited thereto.

Subsequently, the step of milling the matrix material on which calcination ends may be putting the matrix material into Nalgene bottle along with YSZ ball and a solvent (ethanol) and milling the matrix material by a ball milling process to form small particles, but embodiments of the present disclosure are not limited thereto.

Moreover, the milling step may further include a drying step of separating a powder mixed with the solvent after the milling step. Here, the drying step may put the milled matrix material into a dish and may sufficiently dry the milled matrix material at a temperature of 90° C. to 100° C. For example, drying may be performed for 3 hours, but embodiments of the present disclosure are not limited thereto.

According to an embodiment of the present disclosure, the step of milling the phase-synthesized matrix material may further include sieving a material.

The sieving step may be filtering out dried powders finely grinded by the mortar by a 40-mesh sieve to produce powders including particles having a certain size or less. A powder passing through the 40-mesh sieve may have a size of 400 μm or less, but embodiments of the present disclosure are not limited thereto.

Next, the step of preparing a molded body by molding (or press molding) a slurry may be a step of manufacturing a molded body with a predetermined volume and shape from a granulated parent material prepared in the previous step.

For example, the molded body may be prepared by putting a granulated parent material in a molding mold and performing a pressurized press process. For example, the pressurized press process may include uniaxial press or hot press and cold isostatic press, but the embodiments of the present disclosure are not limited thereto. High-density characteristics of the vibration layer may be improved by the pressurized press process.

Next, the step of preparing a sintered body by sintering the molded body may be a step of putting the molded body in a furnace, maintaining the molded body for 30 minutes after raising a room temperature of 25° C. to 400° C. at a heating rate of 5° C./min, maintaining the molded body for 6 hours after raising the temperature of 400° C. to 1,090° C. at a heating rate of 5° C./min and cooling or naturally cooling the molded body at a normal temperature (or room temperature), but the embodiments of the present disclosure are not limited thereto. An additive may be further added in the sintering process. For example, the additive may include an oxide or an inorganic compound, but the embodiments of the present disclosure are not limited thereto. The oxide may include cobalt oxide, aluminum oxide or iron oxide, but the embodiments of the present disclosure are not limited thereto. For example, the oxide may be CoO, Al₂O₃, Co₃O₄ or Fe₂O₃, but the embodiments of the present disclosure are not limited thereto. The inorganic compound may be a chlorine (Cl)-based compound or a fluorine (F)-based compound, but the embodiments of the present disclosure are not limited thereto. Since an additive is further added in the sintering process, high-density characteristics of the vibration layer 11a may be improved.

The sintering process of the parent material according to another example may be spark plasma sintering or thermal isotropic sintering, but the embodiments of the present disclosure are not limited thereto.

Next, in the process of growing the sintered body (or vibration layer), the sintered body (or vibration layer) is used as a KNN-based parent material, and the process may include forming the sintered body on the vehicle interior material (or glass substrate) through vacuum deposition (or sputtering process).

For example, the step may include a step of forming or growing the first electrode layer 11b by using glass, which is an interior material of the vehicular apparatus, as a substrate. The step may include a step of forming or growing the vibration layer 11a after the step of forming or growing the first electrode layer 11b. The KNN-based material may be crystallized through a heat treatment process. The heat treatment process may be a firing process. The temperature during the heat treatment process may be 400° C., but the embodiments of the present disclosure are not limited thereto.

Next, the first line 13 and the second line 15 may be formed through an etching process.

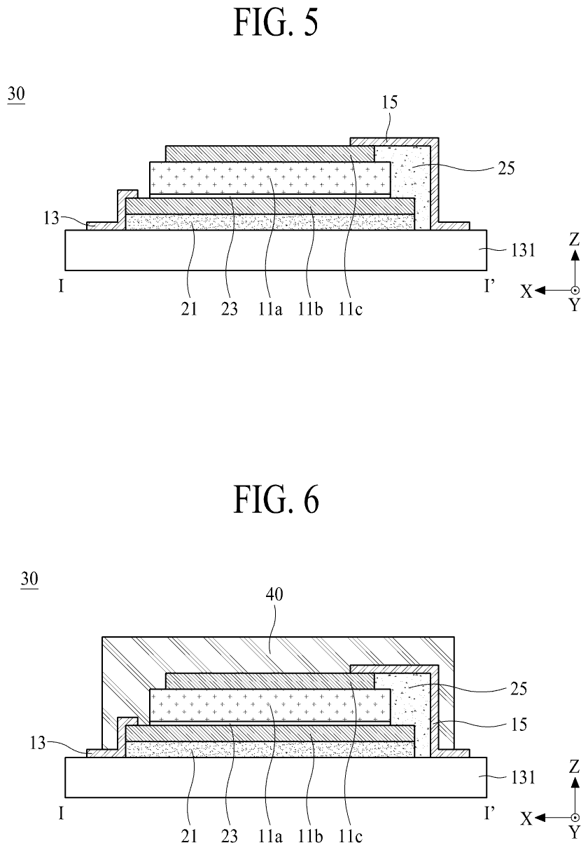

FIG. 5 is a view illustrating a sound apparatus according to another embodiment of the present disclosure.

Referring to FIG. 5, the vehicular apparatus according to another embodiment of the present disclosure may include a sound apparatus 30 or a vibration device, which is disposed on the vibration member 131.

According to another embodiment of the present disclosure, the sound apparatus 30 or the vibration device may include a first vibration layer 11a, a first electrode layer 11b, and a second electrode layer 11c. Since the description of the layers is substantially the same as that described in FIGS. 3 and 4, the same reference numerals will be given, and their redundant description will be omitted.

According to another embodiment of the present disclosure, the sound apparatus 30 or the vibration device may further include a second vibration layer 23. The vibration layer 11a may be the first vibration layer 11a.

For example, the second vibration layer 23 may be provided under the vibration layer or the first vibration layer 11a. Thus, the second vibration layer 23 may allow the first vibration layer 11a to be stably formed or grown in a direction of (001) before the first vibration layer 11a is formed or deposited. For example, the second vibration layer 23 may be a seed layer, but the embodiments of the present disclosure are not limited thereto.

The first vibration layer 11a may be on or disposed on the first electrode layer 11b. The second electrode layer 11c may be on or disposed on the first vibration layer 11a. The second vibration layer 23 may be disposed between the first electrode layer 11b and the first vibration layer 11a.

For example, the second vibration layer 23 may include a piezoelectric material. The second vibration layer 23 may be made of the same material as that of the first vibration layer 11a, but the embodiments of the present disclosure are not limited thereto. For example, the second vibration layer 23 may be made of a material having a perovskite structure, but the embodiments of the present disclosure are not limited thereto. For example, the second vibration layer 23 may include NaNbO₃, SrTiO₃, CaZrO₃, BaZrO₃, (K,Na)NbO₃ or the like, but the embodiments of the present disclosure are not limited thereto.

A thickness of the second vibration layer 23 may be equal to or smaller than that of the first vibration layer 11a, but the embodiments of the present disclosure are not limited thereto. For example, the thickness of the second vibration layer 23 may be 0.5 μm or less or 0.3 μm or less, but the embodiments of the present disclosure are not limited thereto. When the thickness of the second vibration layer 23 is greater than that of the first vibration layer 11a, piezoelectric characteristics are lower than those of the first vibration layer 11a, and thus sufficient sound pressure characteristics cannot be obtained.

A size of the second vibration layer 23 may be the same as that of the first vibration layer 11a, but the embodiments of the present disclosure are not limited thereto.

According to another embodiment of the present disclosure, the sound apparatus 30 or the vibration device may further include an adhesive member 21. The adhesive member 21 may be disposed between the substrate or the vibration member 131 and the first electrode layer 11b. The sound apparatus 30 or the vibration device may be connected to or coupled to the substrate or the vibration member 131 by the adhesive member 21. For example, the sound apparatus 30 or the vibration device may be connected to or coupled to the substrate or the first surface of the vibration member 131 by the adhesive member 21.

For example, the adhesive member 21 may include epoxy resin, acrylic resin, silicone resin, or urethane resin, but embodiments of the present disclosure are not limited thereto.

For example, the adhesive member 21 may include an adhesive layer (or a viscosity layer) having excellent adhesion or adhesive force. For example, the adhesive member 21 may include an adhesive, a double-sided adhesive, a double-sided tape, a double-sided adhesive tape, a double-sided adhesive foam tape, a double-sided foam pad, a double-sided adhesive foam pad, a double-sided cushion tape or an adhesive sheet, but the embodiments of the present disclosure are not limited thereto.

The sound apparatus 30 or the vibration device may include a first line 13 and a second line 15. The first line 13 may be connected to the first electrode layer 11b. For example, the first line 13 may be provided on a side of the first electrode layer 11b. For example, the first line 13 may be formed on sides of the first electrode layer 11b and the adhesive member 21. The first line 13 may be in contact with or in direct contact with the vibration member 131. The second line 15 may be connected to the second electrode layer 11c. For example, the second line 15 may be connected to a portion of an upper surface of the second electrode layer 11c. The second line 15 may be in contact with or in direct contact with the vibration member 131.

The sound apparatus 30 or the vibration device may further include an insulating layer 25 around the second electrode layer 11c. For example, the insulating layer 25 may be on sides of one or more of the first vibration layer 11a and the second electrode layer 11c. The insulating layer 25 may be on sides of the first vibration layer 11a, the second electrode layer 11c, and the second vibration layer 23. The insulating layer 25 may be made of zinc oxide (ZnO) or aluminum oxide (Al₂O₃), but the embodiments of the present disclosure are not limited thereto.

For example, the second line 15 may be provided on a portion of the upper surface of the second electrode layer 11c and around the insulating layer 25. The second line 15 may be provided to cover a portion of the upper surface of the second electrode layer 11c and the insulating layer 25.

Since the method of manufacturing the sound apparatus 30 according to the present disclosure is substantially the same as that described in FIGS. 3 and 4, its description will be omitted.

The second vibration layer 23 may be made of a parent material of NaNbO₃ or SrTiO₃, but the embodiments of the present disclosure are not limited thereto. The method of manufacturing the second vibration layer 23 using the parent material may be performed in substantially the same process as the method of manufacturing the first vibration layer 11a. Since the second vibration layer 23 is substantially the same as that described in FIGS. 3 and 4, its description will be omitted.

Referring to FIG. 2 together, the vehicular apparatus according to another embodiment of the present disclosure may include a vibration member 131 and a sound apparatus 30 disposed on the vibration member 131. The vibration member 131 may be made of glass. The sound apparatus 30 may be configured to vibrate the vibration member 131 or to be directly vibrated, thereby outputting sound according to the vibration of the vibration member 131.

Referring to FIG. 2 together, the sound apparatus 30 may be configured to be transparent and may be disposed in a middle area or a peripheral area of the vehicle window 230. For example, the sound apparatus 30 may be disposed in a middle area or a peripheral area of one or more of the side window 241, the rear window 242, and the roof window.

According to another embodiment of the present disclosure, since the second vibration layer 23 is provided below the first vibration layer 11a, the first vibration layer 11a may be stably provided by the second vibration layer 23.

FIG. 6 is a view illustrating a sound apparatus according to another embodiment of the present disclosure.

Referring to FIG. 6, the vehicular apparatus according to another embodiment of the present disclosure may include a sound apparatus 30 or a vibration device, which is disposed on the vibration member 131.

According to another embodiment of the present disclosure, the sound apparatus 30 or the vibration device may include a first vibration layer 11a, a first electrode layer 11b, and a second electrode layer 11c. Since the description of the sound apparatus 30 or the vibration device is substantially the same as that described in FIGS. 3 and 4, the same reference numerals will be given, and their redundant description will be omitted. The sound apparatus according to another embodiment of the present disclosure may further include a second vibration layer 23. Since the description of the second vibration layer 23 is substantially the same as that described in FIG. 5, the same reference numerals will be given, and their redundant description will be omitted.

The vehicular apparatus according to another embodiment of the present disclosure may further include an auxiliary layer 40. The description of the auxiliary layer 40 may be equally applied to FIGS. 4 and 5.

For example, the auxiliary layer 40 may be disposed on the second electrode layer 11c. The auxiliary layer 40 may be made of the same material as reflectance of the second electrode layer 11c, but the embodiments of the present disclosure are not limited thereto. For example, the auxiliary layer 40 may be made of the same material as reflectance of one of the second electrode layer 11c and the air layer, but the embodiments of the present disclosure are not limited thereto. For example, the auxiliary layer 40 may be a silicon-based compound or the like, but the embodiments of the present disclosure are not limited thereto. For example, the auxiliary layer 40 may be a tetra ethyl ortho silicate (TEOS) or a silane coupling agent, but the embodiments of the present disclosure are not limited thereto. Accordingly, transmittance of the sound apparatus 30 may be improved.

Since the method of manufacturing the sound apparatus 30 according to the present disclosure is substantially the same as that described in FIGS. 3 and 4, its description will be omitted.

The second vibration layer 23 may be made of a parent material of NaNbO₃ or SrTiO₃, but the embodiments of the present disclosure are not limited thereto. The method of manufacturing the second vibration layer 23 using the parent material may be performed in substantially the same process as the method of manufacturing the first vibration layer 11a. Since the description of the manufacturing method is substantially the same as that described in FIG. 3 and FIG. 4, its description will be omitted.

Referring to FIG. 2 together, the vehicular apparatus may include a vibration member 131 and a sound apparatus 30 disposed on the vibration member 131. The vibration member 131 may be made of glass. The sound apparatus 30 may be configured to vibrate the vibration member 131 or to be directly vibrated, thereby outputting sound according to the vibration of the vibration member 131.

Referring to FIG. 2 together, the sound apparatus 30 may be configured to be transparent and may be disposed in a middle area or a peripheral area of the vehicle window 230. For example, the sound apparatus 30 may be disposed in a middle area or a peripheral area of one or more of the side window 241, the rear window 242, and the roof window.

According to another embodiment of the present disclosure, since the auxiliary layer 40 is further provided, the sound apparatus with improved transmittance may be provided.

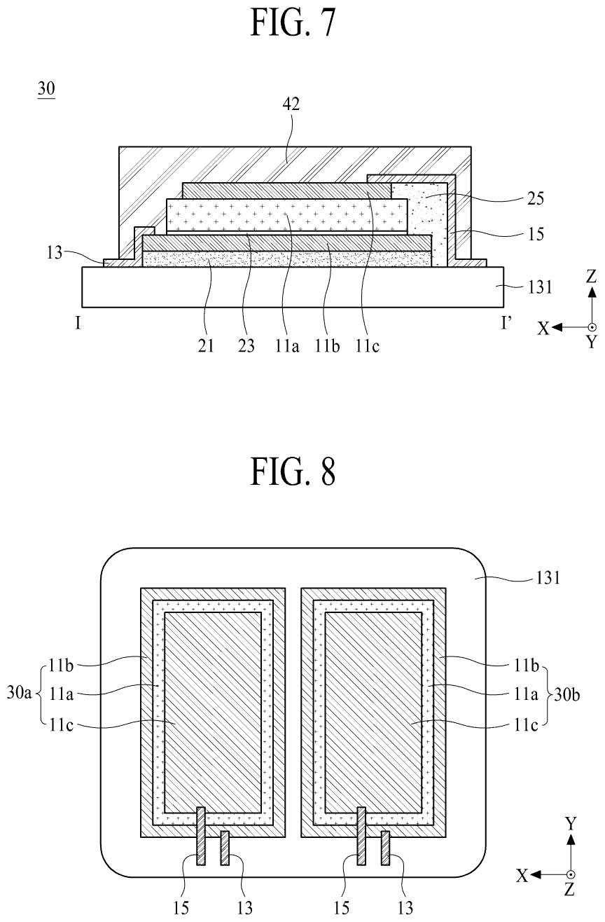

FIG. 7 is a view illustrating a sound apparatus according to another embodiment of the present disclosure.

Referring to FIG. 7, the vehicular apparatus according to another embodiment of the present disclosure may include a sound apparatus 30 or a vibration device, which is disposed on the vibration member 131.

According to another embodiment of the present disclosure, the sound apparatus 30 or the vibration device may include a vibration layer 11a, a first electrode layer 11b, and a second electrode layer 11c. Since the description of the sound apparatus 30 or the vibration device is substantially the same as that described in FIGS. 3 and 4, the same reference numerals will be given, and their redundant description will be omitted. The sound apparatus according to another embodiment of the present disclosure may further include a second vibration layer 23. Since the description of the second vibration layer 23 is substantially the same as that described in FIG. 5, the same reference numerals will be given, and their redundant description will be omitted.

The sound apparatus according to another embodiment of the present disclosure may further include an auxiliary layer 42. The description of the auxiliary layer 42 may be equally applied to FIGS. 4 and 5.

For example, the auxiliary layer 42 may be disposed on the second electrode layer 11c. The auxiliary layer 42 may be made of the same material as impedance of the second vibration layer 23, but the embodiments of the present disclosure are not limited thereto. For example, the auxiliary layer 42 may be made of the same material as impedance of one of the second vibration layer 23 and the second electrode layer 11c, but the embodiments of the present disclosure are not limited thereto. For example, the auxiliary layer 42 may be made of the same material as impedance of one of the second vibration layer 23, the second electrode layer 11c and the air layer, but the embodiments of the present disclosure are not limited thereto. For example, the auxiliary layer 42 may be an acrylic-based or silicon-based material, but the embodiments of the present disclosure are not limited thereto. Accordingly, sound pressure characteristics and/or sound characteristics of the sound apparatus 30 may be improved.

According to another embodiment of the present disclosure, since the auxiliary layer 42 is further provided, the sound apparatus 30 with improved sound pressure characteristics and/or sound characteristics may be provided.

Since the method of manufacturing the sound apparatus 30 according to the present disclosure is substantially the same as that described in FIGS. 3 and 4, its description will be omitted.

The second vibration layer 23 may be made of a parent material of NaNbO₃ or SrTiO₃, but the embodiments of the present disclosure are not limited thereto. The method of manufacturing the second vibration layer 23 using the parent material may be performed in substantially the same process as the method of manufacturing the first vibration layer 11a. Since the manufacturing method is substantially the same as that described in FIG. 3 and FIG. 4, its description will be omitted.

Referring to FIG. 2 together, the vehicular apparatus may include a vibration member 131 and a sound apparatus 30 disposed on the vibration member 131. The vibration member 131 may be made of glass. The sound apparatus 30 may be configured to vibrate the vibration member 131 or to be directly vibrated, thereby outputting sound according to the vibration of the vibration member 131.

Referring to FIG. 2 together, the sound apparatus 30 may be configured to be transparent and may be disposed in a middle area or a peripheral area of the vehicle window 230. For example, the sound apparatus 30 may be disposed in a middle area or a peripheral area of one or more of the side window 241, the rear window 242, and the roof window.

FIG. 8 is a plan view illustrating a sound apparatus according to another embodiment of the present disclosure.

Referring to FIG. 8, the vehicular apparatus according to another embodiment of the present disclosure may include a sound apparatus 30 disposed on the vibration member 131.

According to another embodiment of the present disclosure, the sound apparatus 30 may include one or more vibration devices. For example, the one or more vibration devices may include two vibration devices 30a and 30b. For example, the two vibration devices 30a and 30b may include a first vibration device 30a and a second vibration device 30b.

Each of the first vibration device 30a and the second vibration device 30b may include a first vibration layer 11a, a first electrode layer 11b, and a second electrode layer 11c. As another example, each of the first vibration device 30a and the second vibration device 30b may include a first vibration layer 11a, a first electrode layer 11b, a second electrode layer 11c, and a second vibration layer 23. Since the first and second vibration devices 30a and 30b is substantially the same as those described in FIGS. 3 to 5, their description will be omitted.

Each of the first vibration device 30a and the second vibration device 30b may include a first line 13 and a second line 15.

The first electrode layer 11b of each of the first vibration device 30a and the second vibration device 30b may be connected to the first line 13 of each of the first vibration device 30a and the second vibration device 30b. For example, the first electrode layer 11b of the first vibration device 30a may be connected to the first line 13 of the first vibration device 30a. For example, the first electrode layer 11b of the second vibration device 30b may be connected to the first line 13 of the second vibration device 30b.

The second electrode layer 11c of each of the first vibration device 30a and the second vibration device 30b may be connected to the second line 15 of each of the first vibration device 30a and the second vibration device 30b. For example, the second electrode layer 11c of the first vibration device 30a may be connected to the second line 15 of the first vibration device 30a. For example, the second electrode layer 11c of the second vibration device 30b may be connected to the second line 15 of the second vibration device 30b. Accordingly, the sound apparatus 30 according to another embodiment of the present disclosure may be implemented with two channels.

According to the present disclosure, the sound apparatus 30 integrated with the vibration member 131 or the vehicle interior material may be provided. For example, the vehicle interior material in which the sound apparatus 30 is integrated may be implemented. For example, the vehicle interior material in which the sound apparatus 30 capable of implementing two channels is integrated may be configured.

Referring to FIG. 2 together, the vehicular apparatus may include a vibration member 131 and a sound apparatus 30 disposed on the vibration member 131. The vibration member 131 may be made of glass. The sound apparatus 30 may be configured to vibrate the vibration member 131 or to be directly vibrated, thereby outputting sound according to the vibration of the vibration member 131.

Referring to FIG. 2 together, the sound apparatus 30 may be configured to be transparent and may be disposed in a middle area or a peripheral area of the vehicle window 230. For example, the sound apparatus 30 may be disposed in a middle area or a peripheral area of one or more of the side window 241, the rear window 242, and the roof window.

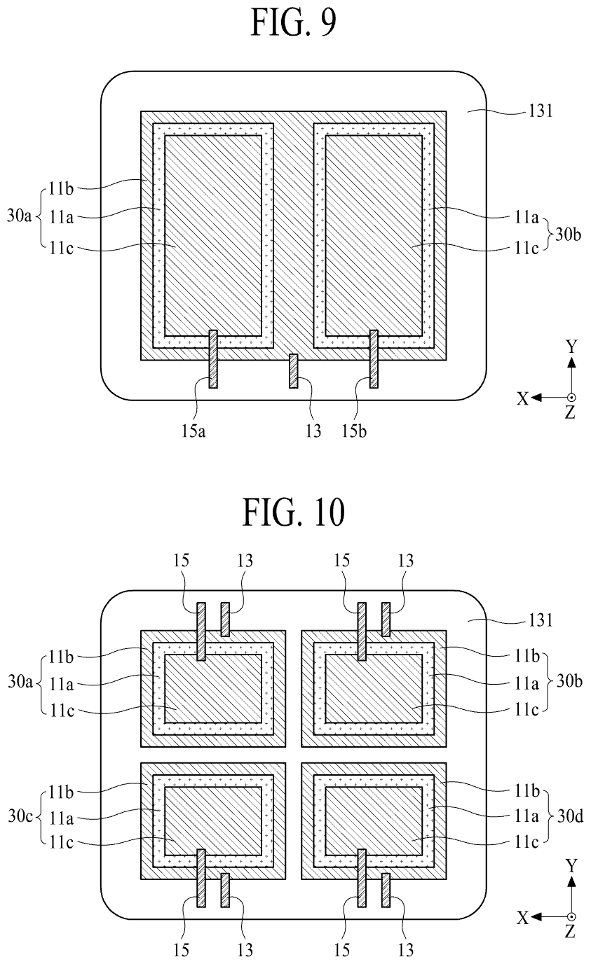

FIG. 9 is a plan view illustrating a sound apparatus according to another embodiment of the present disclosure.

Referring to FIG. 9, the vehicular apparatus according to another embodiment of the present disclosure may include a sound apparatus 30 disposed on the vibration member 131.

According to another embodiment of the present disclosure, the sound apparatus 30 may include one or more vibration devices. For example, the one or more vibration devices may include two vibration devices 30a and 30b. For example, the two vibration devices 30a and 30b may include a first vibration device 30a and a second vibration device 30b.

Each of the first vibration device 30a and the second vibration device 30b may include a first vibration layer 11a, a first electrode layer 11b, and a second electrode layer 11c. As another example, each of the first vibration device 30a and the second vibration device 30b may include a first vibration layer 11a, a first electrode layer 11b, a second electrode layer 11c, and a second vibration layer 23. Since the first and second vibration devices 30a and 30b is substantially the same as those described in FIGS. 3 to 5, the same reference numerals will be given, and their redundant description will be omitted.

The first vibration device 30a and the second vibration device 30b may include a first line 13 and second lines 15a and 15b.

The first electrode layer 11b of each of the first vibration device 30a and the second vibration device 30b may be connected in common to the first line 13. For example, the first electrode layer 11b of the first vibration device 30a may be connected in common to the first line 13 of the first vibration device 30a. For example, the first electrode layer 11b of the second vibration device 30b may be connected in common to the first line 13 of the second vibration device 30b.

The second electrode layer 11c of each of the first vibration device 30a and the second vibration device 30b may be connected to the second lines 15a and 15b of each of the first vibration device 30a and the second vibration device 30b. For example, the second electrode layer 11c of the first vibration device 30a may be connected to the second line 15a of the first vibration device 30a. For example, the second electrode layer 11c of the second vibration device 30b may be connected to the second line 15b of the second vibration device 30b.

According to the present disclosure, the sound apparatus 30 integrated with the vibration member 131 or the vehicle interior material may be provided. For example, the vehicle interior material in which the sound apparatus 30 is integrated may be implemented. For example, since the first vibration device 30a and the second vibration device 30b are connected in common to the first line 13, the sound apparatus 30 with a simplified process may be implemented.

Referring to FIG. 2 together, the vehicular apparatus may include a vibration member 131 and a sound apparatus 30 disposed on the vibration member 131. The vibration member 131 may be made of glass. The sound apparatus 30 may be configured to vibrate the vibration member 131 or to be directly vibrated, thereby outputting sound according to the vibration of the vibration member 131.

Referring to FIG. 2 together, the sound apparatus 30 may be configured to be transparent and may be disposed in a middle area or a peripheral area of the vehicle window 230. For example, the sound apparatus 30 may be disposed in a middle area or a peripheral area of one or more of the side window 241, the rear window 242, and the roof window.

FIG. 10 is a plan view illustrating a sound apparatus according to another embodiment of the present disclosure.

Referring to FIG. 10, the vehicular apparatus according to another embodiment of the present disclosure may include a sound apparatus 30 disposed on the vibration member 131.

According to another embodiment of the present disclosure, the sound apparatus 30 may include one or more vibration devices. For example, the one or more vibration devices may include four vibration devices 30a, 30b, 30c and 30d. For example, the four vibration devices 30a, 30b, 30c and 30d may include first to fourth vibration devices 30a, 30b, 30c and 30d.

Each of the first to fourth vibration devices 30a, 30b, 30c and 30d may include a first vibration layer 11a, a first electrode layer 11b, and a second electrode layer 11c. As another example, each of the first to fourth vibration devices 30a, 30b, 30c and 30d may include a first vibration layer 11a, a first electrode layer 11b, a second electrode layer 11c, and a second vibration layer 23. Since the vibration devices are substantially the same as those described in FIGS. 3 to 5, the same reference numerals will be given, and their redundant description will be omitted.

Each of the first to fourth vibration devices 30a, 30b, 30c and 30d may include a first line 13 and a second line 15.

The first electrode layer 11b of each of the first to fourth vibration devices 30a, 30b, 30c and 30d may be connected to the first line 13 of each of the first to fourth vibration devices 30a, 30b, 30c and 30d. For example, the first electrode layer 11b of the first vibration device 30a may be connected to the first line 13 of the first vibration device 30a. For example, the first electrode layer 11b of the second vibration device 30b may be connected to the first line 13 of the second vibration device 30b. For example, the first electrode layer 11b of the third vibration device 30c may be connected to the first line 13 of the third vibration device 30c. For example, the first electrode layer 11b of the fourth vibration device 30d may be connected to the first line 13 of the fourth vibration device 30d.

The second electrode layer 11c of each of the first to fourth vibration devices 30a, 30b, 30c and 30d may be connected to the second line 15 of each of the first to fourth vibration devices 30a, 30b, 30c and 30d. For example, the second electrode layer 11c of the first vibration device 30a may be connected to the second line 15 of the first vibration device 30a. For example, the second electrode layer 11c of the second vibration device 30b may be connected to the second line 15 of the second vibration device 30b. For example, the first electrode layer 11b of the third vibration device 30c may be connected to the second line 15 of the third vibration device 30c. For example, the first electrode layer 11b of the fourth vibration device 30d may be connected to the second line 15 of the fourth vibration device 30d. Accordingly, the sound apparatus 30 according to another embodiment of the present disclosure may be implemented with four channels. According to the present disclosure, the number of channels may be easily controlled in the same process of the sound apparatus 30.

According to the present disclosure, the sound apparatus 30 integrated with the vibration member 131 or the vehicle interior material may be provided. For example, the vehicle interior material in which the sound apparatus 30 is integrated may be implemented. For example, the vehicle interior material in which the sound apparatus 30 capable of implementing four channels is integrated may be configured.

Referring to FIG. 2 together, the vehicular apparatus may include a vibration member 131 and a sound apparatus 30 disposed on the vibration member 131. The vibration member 131 may be made of glass. The sound apparatus 30 may be configured to vibrate the vibration member 131 or to be directly vibrated, thereby outputting sound according to the vibration of the vibration member 131.

Referring to FIG. 2 together, the sound apparatus 30 may be configured to be transparent and may be disposed in a middle area or a peripheral area of the vehicle window 230. For example, the sound apparatus 30 may be disposed in a middle area or a peripheral area of one or more of the side window 241, the rear window 242, and the roof window.

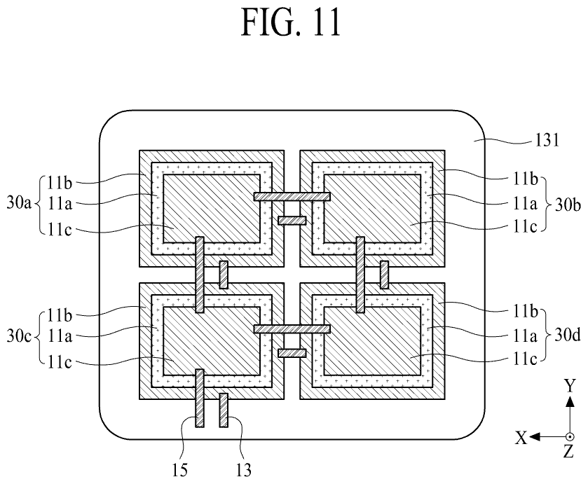

FIG. 11 is a plan view illustrating a sound apparatus according to another embodiment of the present disclosure.

Referring to FIG. 11, the vehicular apparatus according to another embodiment of the present disclosure may include a sound apparatus 30 disposed on the vibration member 131.

According to another embodiment of the present disclosure, the sound apparatus 30 may include one or more vibration devices. For example, the one or more vibration devices may include four vibration devices 30a, 30b, 30c and 30d. For example, the four vibration devices 30a, 30b, 30c and 30d may include first to fourth vibration devices 30a, 30b, 30c and 30d.

Each of the first to fourth vibration devices 30a, 30b, 30c and 30d may include a first vibration layer 11a, a first electrode layer 11b, and a second electrode layer 11c. As another example, each of the first to fourth vibration devices 30a, 30b, 30c and 30d may include a first vibration layer 11a, a first electrode layer 11b, a second electrode layer 11c, and a second vibration layer 23. Since the vibration devices are substantially the same as those described in FIGS. 3 to 5, the same reference numerals will be given, and their redundant description will be omitted.

Each of the first to fourth vibration devices 30a, 30b, 30c and 30d may include a first line 13 and a second line 15.

According to the present disclosure, the first electrode layer 11b of each of the first to fourth vibration devices 30a, 30b, 30c and 30d may be connected in common to the first line 13. The second electrode layer 11c in each of the first to fourth vibration devices 30a, 30b, 30c and 30d may be connected in common to the second line 15.

According to the present disclosure, the first electrode layer 11b of the first vibration device 30a and the first electrode layer 11b of the second vibration device 30b may be connected to the first line 13. For example, the first electrode layer 11b of the first vibration device 30a and the first electrode layer 11b of the second vibration device 30b may be connected in common to the first line 13. The second electrode layer 11c of the first vibration device 30a and the second electrode layer 11c of the second vibration device 30b may be connected to the second line 15. For example, the second electrode layer 11c of the first vibration device 30a and the second electrode layer 11c of the second vibration device 30b may be connected in common to the second line 15.

According to the present disclosure, the first electrode layer 11b of the first vibration device 30a and the first electrode layer 11b of the third vibration device 30c may be connected to the first line 13. For example, the first electrode layer 11b of the first vibration device 30a and the first electrode layer 11b of the third vibration device 30c may be connected in common to the first line 13. The second electrode layer 11c of the first vibration device 30a and the second electrode layer 11c of the third vibration device 30c may be connected to the second line 15. For example, the second electrode layer 11c of the first vibration device 30a and the second electrode layer 11c of the third vibration device 30c may be connected in common to the second line 15.

According to the present disclosure, the first electrode layer 11b of the second vibration device 30b and the first electrode layer 11b of the fourth vibration device 30d may be connected to the first line 13. For example, the first electrode layer 11b of the second vibration device 30b and the first electrode layer 11b of the fourth vibration device 30d may be connected in common to the first line 13. The second electrode layer 11c of the second vibration device 30b and the second electrode layer 11c of the fourth vibration device 30d may be connected to the second line 15. For example, the second electrode layer 11c of the second vibration device 30b and the second electrode layer 11c of the fourth vibration device 30d may be connected in common to the second line 15.

According to the present disclosure, the first electrode layer 11b of the third vibration device 30c and the first electrode layer 11b of the fourth vibration device 30d may be connected to the first line 13. For example, the first electrode layer 11b of the third vibration device 30c and the first electrode layer 11b of the fourth vibration device 30d may be connected in common to the first line 13. The second electrode layer 11c of the third vibration device 30c and the second electrode layer 11c of the fourth vibration device 30d may be connected to the second line 15. For example, the second electrode layer 11c of the third vibration device 30c and the second electrode layer 11c of the fourth vibration device 30d may be connected in common to the second line 15.

Accordingly, the sound apparatus 30 according to another embodiment of the present disclosure may be implemented with one channel.

According to the present disclosure, the sound apparatus 30 integrated with the vibration member 131 or the vehicle interior material may be provided. For example, the vehicle interior material in which the sound apparatus 30 is integrated may be implemented. For example, the vehicle interior material in which the sound apparatus 30 capable of implementing one channel is integrated may be configured.

Referring to FIG. 2 together, the vehicular apparatus may include a vibration member 131 and a sound apparatus 30 disposed on the vibration member 131. The vibration member 131 may be made of glass. The sound apparatus 30 may be configured to vibrate the vibration member 131 or to be directly vibrated, thereby outputting sound according to the vibration of the vibration member 131.

Referring to FIG. 2 together, the sound apparatus 30 may be configured to be transparent and may be disposed in a middle area or a peripheral area of the vehicle window 230. For example, the sound apparatus 30 may be disposed in a middle area or a peripheral area of one or more of the side window 241, the rear window 242, and the roof window.

A sound apparatus and vehicular apparatus comprising the same according to example embodiments of the present disclosure are described below.

A sound apparatus according to one or more embodiments of the present disclosure may be configured for use with at least one of a vibration member and an interior material of a vehicular apparatus and configured to output sound. The sound apparatus may include a first electrode layer, a first vibration layer on the first electrode layer, a second electrode layer on the first vibration layer, a first line connected to the first electrode layer and in contact with the vibration member, and a second line connected to the second electrode layer and in contact with the vibration member.

According to one or more embodiments of the present disclosure, the first vibration layer may include at least one of a PZT-based material, a KNN-based material, a BT-based material, a Bi-based material, and AlN.

According to one or more embodiments of the present disclosure, the sound apparatus may further comprise an insulating layer around the first electrode layer, the first vibration layer and the second electrode layer.

According to one or more embodiments of the present disclosure, a size of the second electrode layer may smaller than a size of the first vibration layer.

According to one or more embodiments of the present disclosure, a size of the first electrode layer may be larger than a size of the second electrode layer.

According to one or more embodiments of the present disclosure, the sound apparatus may include two vibration devices, and the first electrode layer in each of the two vibration devices may be connected in common to the first line.

According to one or more embodiments of the present disclosure, the sound apparatus may include four vibration devices, and the first electrode layer in each of the four vibration devices may be connected in common to the first line, and the second electrode layer in each of the four vibration devices may be connected in common to the second line.

According to one or more embodiments of the present disclosure, the sound apparatus may further comprise a second vibration layer between the first electrode layer and the first vibration layer.

According to one or more embodiments of the present disclosure, the second vibration layer may contain a piezoelectric material.

According to one or more embodiments of the present disclosure, the sound apparatus may further comprise an insulating layer around the first electrode layer, the first vibration layer, the second electrode layer, and the second vibration layer.

According to one or more embodiments of the present disclosure, the sound apparatus may further comprising an auxiliary layer on the second electrode layer.

According to one or more embodiments of the present disclosure, the auxiliary layer may be made of a material having the same reflectance as the second electrode layer.

According to one or more embodiments of the present disclosure, the auxiliary layer may be made of a material having the same impedance as one of the second vibration layer and the second electrode layer.

According to one or more embodiments of the present disclosure, a thickness of the first vibration layer may be equal to or thicker than a thickness of the second vibration layer.

According to one or more embodiments of the present disclosure, the sound apparatus may include two vibration devices, and the first electrode layer in each of the two vibration devices may be connected in common to the first line.

According to one or more embodiments of the present disclosure, the sound apparatus may include four vibration devices, and the first electrode layer in each of the four vibration devices may be connected in common to the first line, and the second electrode layer in each of the four vibration devices may be connected in common to the second line.

A vehicular apparatus according to one or more embodiments of the present disclosure may comprises a vibration member, an interior material, and at least one sound apparatus, wherein the at least one sound apparatus includes a sound apparatus, and the sound apparatus may include a first electrode layer, a first vibration layer on the first electrode layer, a second electrode layer on the first vibration layer, a first line connected to the first electrode layer and in contact with the vibration member, and a second line connected to the second electrode layer and in contact with the vibration member.

According to one or more embodiments of the present disclosure, the vibration member may include glass.

According to one or more embodiments of the present disclosure, he vibration member may be at least one of a side window, a rear window and a roof window.

A sound apparatus according to one or more embodiments of the present disclosure may be configured for use with at least one of a vibration member and an interior material of a vehicular apparatus and configured to output sound. The sound apparatus can include a first electrode layer, a first vibration layer on the first electrode layer, a second electrode layer on the first vibration layer, and a second vibration layer between the first electrode layer and the first vibration layer.

According to one or more embodiments of the present disclosure, the first vibration layer and the second vibration layer may contain a piezoelectric material.

According to one or more embodiments of the present disclosure, the sound apparatus may further comprise an insulating layer around the first electrode layer, the first vibration layer, the second electrode layer, and the second vibration layer.

According to one or more embodiments of the present disclosure, the sound apparatus further comprising an auxiliary layer on the second electrode layer.

According to one or more embodiments of the present disclosure, the auxiliary layer may be made of a material having a same reflectance as the second electrode layer.

According to one or more embodiments of the present disclosure, the auxiliary layer may be made of a material having a same impedance as one of the second vibration layer and the second electrode layer.

According to one or more embodiments of the present disclosure, a thickness of the first vibration layer may be equal to or thicker than a thickness of the second vibration layer.

A vehicular apparatus according to one or more embodiments of the present disclosure may comprise a vibration member; an interior material, and at least one sound apparatus, wherein the at least one sound apparatus includes a sound apparatus, and the sound apparatus can include a first electrode layer, a first vibration layer on the first electrode layer, a second electrode layer on the first vibration layer, and a second vibration layer between the first electrode layer and the first vibration layer.

According to one or more embodiments of the present disclosure, the vibration member may include glass.

According to one or more embodiments of the present disclosure, he vibration member may be at least one of a side window, a rear window and a roof window.

A sound apparatus according to an embodiment of the present disclosure may be applied to (or included in) a sound apparatus disposed at a vehicular apparatus. The sound apparatus according to an embodiment of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic book, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game apparatuses, notebook computers, monitors, cameras, camcorders, home appliances, or the like. Addition, the sound apparatus according to some embodiments of the present disclosure may be applied to (or included in) organic light emitting lighting apparatuses or inorganic light emitting lighting apparatuses. When the sound apparatus is applied to (or included in) lighting apparatuses, the lighting apparatuses may act as lighting and a speaker. Addition, when the sound apparatus of the present disclosure is applied to (or included in) a mobile device, or the like, the sound apparatus may act as one or more of a speaker, a receiver, and a haptic device, but embodiments of the present disclosure are not limited thereto.

It will be apparent to those skilled in the art that various modifications and variations can be made in the present disclosure without departing from the scope of the disclosures. Thus, it is intended that the present disclosure covers the modifications and variations of this disclosure that come within the scope of the claims and their equivalents.

What is claimed is:

1. A sound apparatus configured for use with at least one of a vibration member and an interior material of a vehicular apparatus and configured to output sound,
wherein the sound apparatus comprises:
a first electrode layer;
a first vibration layer on the first electrode layer;
a second electrode layer on the first vibration layer;
a first line connected to the first electrode layer and in contact with the vibration member; and
a second line connected to the second electrode layer and in contact with the vibration member.

2. The sound apparatus of claim 1, wherein the first vibration layer includes at least one of a PZT-based material, a KNN-based material, a BT-based material, a Bi-based material, and AlN.

3. The sound apparatus of claim 1, further comprising an insulating layer around the first electrode layer, the first vibration layer and the second electrode layer.

4. The sound apparatus of claim 1, wherein a size of the second electrode layer is smaller than a size of the first vibration layer.

5. The sound apparatus of claim 1, wherein a size of the first electrode layer is larger than a size of the second electrode layer.

6. The sound apparatus of claim 1, wherein the sound apparatus includes two vibration devices, and
the first electrode layer in each of the two vibration devices is connected in common to the first line.

7. The sound apparatus of claim 1, wherein the sound apparatus includes four vibration devices, and
the first electrode layer in each of the four vibration devices is connected in common to the first line, and the second electrode layer in each of the four vibration devices is connected in common to the second line.

8. The sound apparatus of claim 1, further comprising a second vibration layer between the first electrode layer and the first vibration layer.

9. The sound apparatus of claim 8, wherein the second vibration layer contains a piezoelectric material.

10. The sound apparatus of claim 8, further comprising an insulating layer around the first electrode layer, the first vibration layer, the second electrode layer, and the second vibration layer.

11. The sound apparatus of claim 8, further comprising an auxiliary layer on the second electrode layer.

12. The sound apparatus of claim 11, wherein the auxiliary layer is made of a material having a same reflectance as the second electrode layer.

13. The sound apparatus of claim 11, wherein the auxiliary layer is made of a material having a same impedance as one of the second vibration layer and the second electrode layer.

14. The sound apparatus of claim 8, wherein a thickness of the first vibration layer is equal to or thicker than a thickness of the second vibration layer.

15. The sound apparatus of claim 8, wherein the sound apparatus includes two vibration devices, and
the first electrode layer in each of the two vibration devices is connected in common to the first line.

16. The sound apparatus of claim 8, wherein the sound apparatus includes four vibration devices, and
the first electrode layer in each of the four vibration devices is connected in common to the first line, and the second electrode layer in each of the four vibration devices is connected in common to the second line.

17. A vehicular apparatus, comprising:
at least one sound apparatus including the sound apparatus according to claim 1;
the vibration member; and
the interior material.

18. The vehicular apparatus of claim 17, wherein the vibration member includes glass.

19. The vehicular apparatus of claim 17, wherein the vibration member is at least one of a side window, a rear window and a roof window.

20. A sound apparatus configured for use with at least one of a vibration member and an interior material of a vehicular apparatus and configured to output sound,
wherein the sound apparatus includes:
a first electrode layer;
a first vibration layer on the first electrode layer;
a second electrode layer on the first vibration layer; and
a second vibration layer between the first electrode layer and the first vibration layer.

21. The sound apparatus of claim 20, wherein the first vibration layer and the second vibration layer contain a piezoelectric material.

22. The sound apparatus of claim 20, further comprising an insulating layer around the first electrode layer, the first vibration layer, the second electrode layer, and the second vibration layer.

23. The sound apparatus of claim 20, further comprising an auxiliary layer on the second electrode layer.

24. The sound apparatus of claim 23, wherein the auxiliary layer is made of a material having a same reflectance as the second electrode layer.

25. The sound apparatus of claim 23, wherein the auxiliary layer is made of a material having a same impedance as one of the second vibration layer and the second electrode layer.

26. The sound apparatus of claim 20, wherein a thickness of the first vibration layer is equal to or thicker than a thickness of the second vibration layer.

27. A vehicular apparatus, comprising:
at least one sound apparatus including the sound apparatus according to claim 20;
the vibration member; and
the interior material.

28. The vehicular apparatus of claim 27, wherein the vibration member includes glass.

29. The vehicular apparatus of claim 27, wherein the vibration member is at least one of a side window, a rear window and a roof window.
